(19) United States
(12) Patent Application Publication
(10) Pub. No.: US 2026/0287682 A1
(43) Pub. Date: Sep. 24, 2026

(54) ABNORMAL VIBRATION DIAGNOSIS SYSTEM AND METHOD FOR TRANSFORMER

(71) Applicant: Fortune Electric Co., Ltd., Taoyuan City (TW)

(72) Inventors: CHIA-CHING LIN, Taoyuan City (TW); CHING-MIN CHEN, Taoyuan City (TW)

(21) Appl. No.: 19/547,689

(22) Filed: Feb. 24, 2026

(30) Foreign Application Priority Data
Mar. 21, 2025 (TW) 114110666

(51) Int. Cl. G01R 31/62

(52) U.S. Cl. CPC G01R 31/62

(57) ABSTRACT

An abnormal vibration diagnosis system and method for a transformer. The system includes at least one vibration sensor, an analysis device, and a diagnosis device. The at least one vibration sensor is configured to acquire vibration data of a transformer within at least one time interval. The analysis device is connected to the at least one vibration sensor. The analysis device is configured to establish, based on the vibration data, a correlation between a vibration level of the transformer and a tightening force applied to a core assembly of the transformer. The diagnosis device is connected to the analysis device. The diagnosis device is configured to determine, according to the correlation, whether the transformer exhibits abnormal vibration during operation, and to issue an early warning message when the transformer is determined to exhibit the abnormal vibration.

### CROSS-REFERENCE TO RELATED PATENT APPLICATION

This application claims the benefit of priority to Taiwan Patent Application No. 114110666, filed on Mar. 21, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an abnormality diagnosis technology for transformers, and more particularly to an abnormal vibration diagnosis system and method for a transformer.

### BACKGROUND OF THE DISCLOSURE

Transformers are common electrical devices used for decreasing a high voltage to a low voltage or for increasing a low voltage to a high voltage. The operational stability of the transformer is directly related to power supply

reliability of an electrical grid. During operation, a core assembly of the transformer can vibrate under the influence of an electromagnetic field, including vibrations of windings and magnetostriction-induced vibration of a core. The internal vibrations of the transformer can be transmitted from the windings and the core to other components such as support structures, an enclosure, or an oil tank through mechanical structures. Therefore, mechanical vibration is a normal phenomenon during transformer operation.

With an increase in usage time of the transformer, certain mechanical defects may start to develop, such as deformation of the winding or core, loose clamps, deterioration of insulation materials, which may potentially lead to internal faults. In order to detect such internal faults, the transformer is conventionally shut down and disassembled for manual inspection. However, this approach is time-consuming, labor-intensive, and prone to oversight, and in practice, results in low efficiency, high costs, and economic losses caused by power outages.

### SUMMARY OF THE DISCLOSURE

In response to the above-referenced technical inadequacies, the present disclosure provides an abnormal vibration diagnosis system and method for a transformer, which can be used to monitor mechanical vibration of the transformer during operation and identify internal abnormal vibration by analyzing vibration characteristics. This facilitates early detection of potential internal faults of the transformer, thereby reducing the risk of transformer failure.

In order to solve the above-mentioned problems, one of the technical aspects adopted by the present disclosure is to provide an abnormal vibration diagnosis method for a transformer. Firstly, vibration data of a transformer within at least one time interval is acquired. The transformer includes a core assembly, a clamping assembly connected to the core assembly, and an insulator disposed between the core assembly and the clamping assembly, and the clamping assembly is configured to apply a tightening force to the core assembly. Afterwards, a correlation between transformer vibration level and tightening force is established based on the vibration data. Afterwards, whether the transformer exhibits abnormal vibration during operation is determined according to the correlation between transformer vibration level and tightening force. Finally, an early warning message is issued when the transformer is determined to exhibit the abnormal vibration.

In order to solve the above-mentioned problems, another one of the technical aspects adopted by the present disclosure is to provide an abnormal vibration diagnosis system for a transformer. The abnormal vibration diagnosis system includes at least one vibration sensor, an analysis device, and a diagnosis device. The at least one vibration sensor is configured to acquire vibration data of a transformer within at least one time interval. The transformer includes a core assembly, a clamping assembly connected to the core assembly, and an insulator disposed between the core assembly and the clamping assembly, and the clamping assembly is configured to apply a tightening force to the core assembly. The analysis device is connected to the at least one vibration sensor. The analysis device is configured to establish, based on the vibration data, a correlation between transformer vibration level and tightening force. The diagnosis device is connected to the analysis device. The diagnosis device is configured to determine, according to the correlation between transformer vibration level and tightening force, whether the transformer exhibits abnormal vibration during operation, and to issue an early warning message when the transformer is determined to exhibit the abnormal vibration.

In one of the possible or preferred embodiments, the transformer includes an enclosure for accommodating the core assembly, the clamping assembly, and the insulator. The vibration data is acquired by the at least one vibration sensor that is attached to the enclosure or clamping assembly.

In one of the possible or preferred embodiments, the process of determining whether the transformer exhibits the abnormal vibration includes determining, according to the correlation between transformer vibration level and tightening force, whether a type of the abnormal vibration corresponds to a loose winding of the core assembly, a loose core of the core assembly, or deterioration of the insulation. Furthermore, the warning message includes information indicating the type of the abnormal vibration.

In one of the possible or preferred embodiments, the process of determining the type of the abnormal vibration includes identifying an occurrence location of the abnormal vibration by analyzing the vibration data.

In conclusion, the abnormal vibration diagnosis system and method for a transformer provided by the present disclosure can promptly detect looseness in the core or clamping assembly and perform early warning accordingly, and if necessary, can initiate a maintenance measure to prevent transformer failure and ensure safe and stable operation of a power system, by virtue of acquiring vibration data of a transformer within at least one time interval, establishing a correlation between a vibration level of the transformer and a tightening force applied to a core assembly of the transformer, and determining whether the transformer exhibits abnormal vibration during operation according to the correlation.

Furthermore, the abnormal vibration diagnosis system and method for a transformer provided by the present disclosure can realize real-time monitoring, remote supervision, and condition prediction of transformer vibration conditions, fault diagnosis and prevention, thereby enhancing the reliability and safety of the transformer and reducing maintenance costs and labor requirements.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a block diagram of an abnormal vibration diagnosis system for a transformer of the present disclosure;

FIG. 2 is a schematic side view of a transformer to which the abnormal vibration diagnosis system of the present disclosure is applied;

FIG. 3 is a schematic top view of the transformer to which the abnormal vibration diagnosis system of the present disclosure is applied;

FIG. 4 is a schematic view showing an operational arrangement of the abnormal vibration diagnosis system of the present disclosure;

FIG. 5 is another schematic view showing an operational arrangement of the abnormal vibration diagnosis system of the present disclosure;

FIG. 6 is still another schematic view showing an operational arrangement of the abnormal vibration diagnosis system of the present disclosure; and

FIG. 7 is a flowchart of an abnormal vibration diagnosis method for a transformer of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

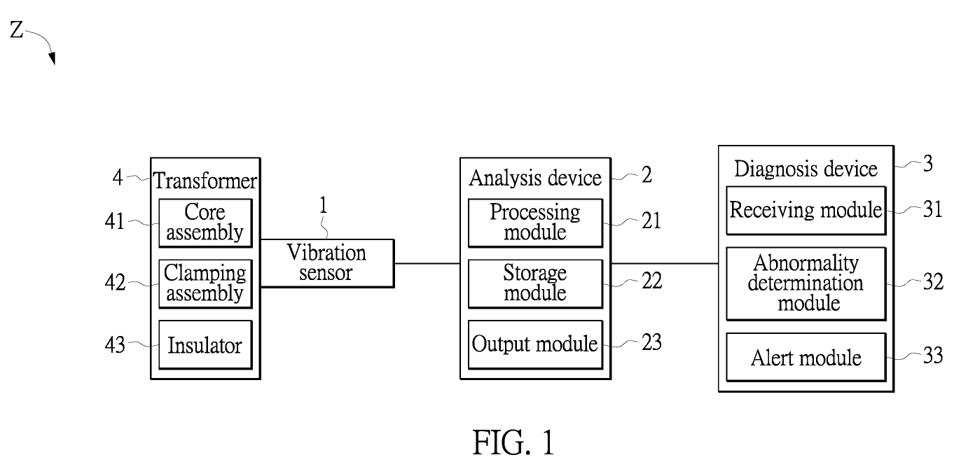

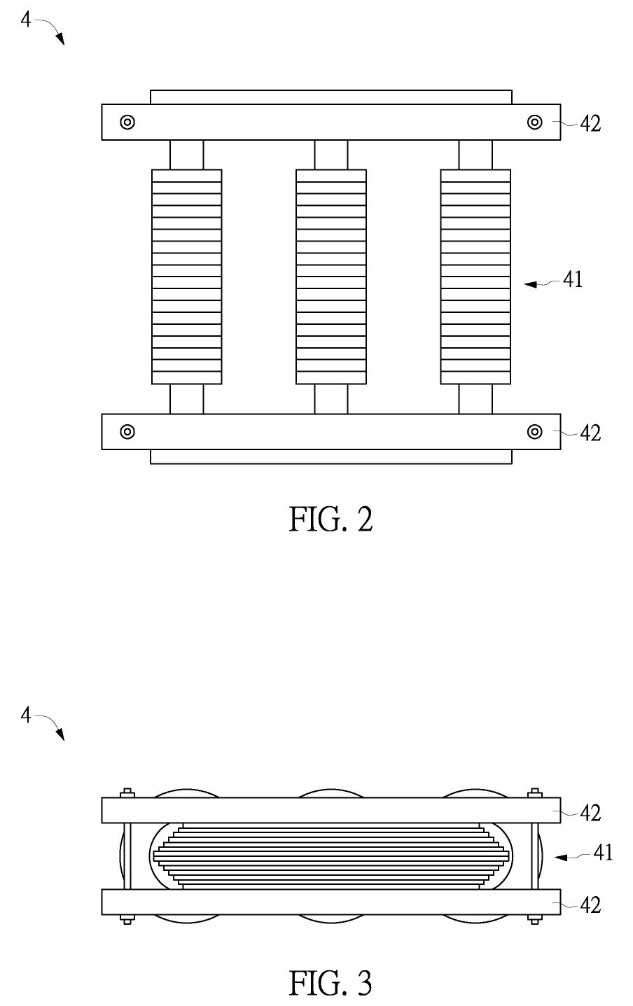

Referring to FIG. 1, which is to be read in conjunction with FIG. 2 to FIG. 6, a first embodiment of the present disclosure provides an abnormal vibration diagnosis system Z, which can be used to monitor mechanical vibrations of a transformer 4 (such as a power or distribution transformer) during operation and detect internal abnormal vibrations of the transformer 4 by analyzing vibration characteristics. Accordingly, early warning and prompt response can be performed immediately after detecting abnormal vibration. The abnormal vibration diagnosis system Z includes at least one vibration sensor 1, an analysis device 2, and a diagnosis device 3. The analysis device 2 can communicate with the at least one vibration sensor 1 via a wired or wireless network. The diagnosis device 3 can communicate with the analysis device 2 via a wired or wireless network.

In the present disclosure, the at least one vibration sensor 1 is configured to acquire vibration data of the transformer 4 within at least one time interval. The analysis device 2 is configured to establish, based on the vibration data, a correlation between a vibration level of the transformer 4 and a tightening force applied to a core assembly 41 of the transformer 4. The diagnosis device 3 is configured to determine, according to the correlation established by the analysis device 2, whether the transformer 4 exhibits abnormal vibration during operation, and to issue an early warning message when the transformer 4 is determined to exhibit the abnormal vibration. Therefore, potential faults inside the transformer 4 can be detected at early stage, thereby reducing the risk of transformer failure.

More specifically, as shown in FIGS. 2 and 3, the transformer 4 to which the abnormal vibration diagnosis system Z of the present disclosure can be applied includes a core assembly 41, a clamping assembly 42, an insulator 43, and an enclosure 44. The core assembly 41, the clamping assembly 42, and the insulator 43 are accommodated in an enclosure 44, in which the clamping assembly 42 is connected to the core assembly 41, and the insulator 43 is disposed between the core assembly 41 and the clamping assembly 42. It should be noted that the clamping assembly 42 is configured to apply a tightening force (i.e., a clamping force) to the core assembly 41. The magnitude of the tightening force can directly affect the vibration level of the transformer 4, and the transformer 4 will exhibit abnormal vibration in response to a significant change in the tightening force. Therefore, a potential fault inside the transformer 4, such as looseness of the core assembly 41 or clamping assembly 42 and deterioration of the insulation 43, can be detected at an early stage, and an early warning can be performed in response to address the potential fault. If necessary, a maintenance measure can be initiated to prevent transformer failure and ensure safe and stable operation of a power system.

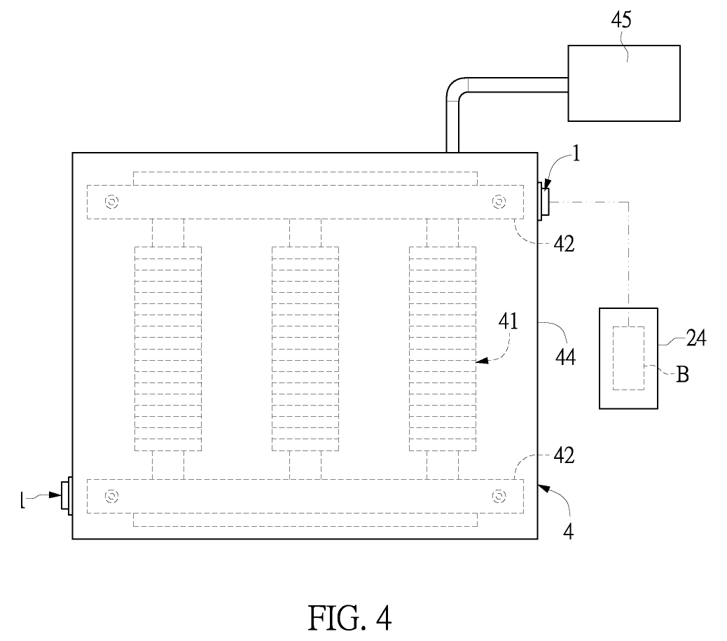

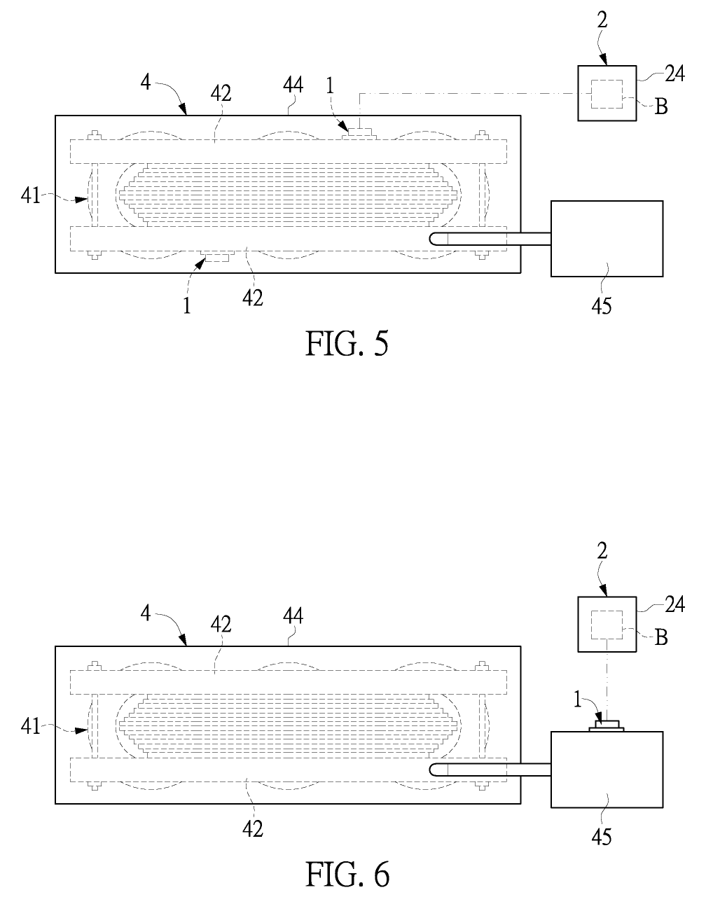

In the present embodiment, the at least one vibration sensor 1 can be installed at a key position of the transformer 4 to acquire vibration data including amplitude, acceleration, frequency, and phase within one or more time intervals and output corresponding electrical signals. A time interval refers to a duration expressed in hours, days, or longer units of time, and the at least one vibration sensor 1 is configured to sample vibration data in an interval, continuous, or timed manner. In practice, the at least one vibration sensor 1 can be one or more sensors for detecting physical quantities associated with vibration, such as force, displacement, or acceleration, and can include, but is not limited to, accelerometers or load cells. Furthermore, the at least one vibration sensor 1 can remain in contact with the enclosure 44 to detect the vibration generated by the enclosure 44, as shown in FIG. 4. Alternatively, the at least one vibration sensor 1 can adopt oil-resistant components and remain in contact with the clamping assembly 42 in the insulating oil to detect the vibration generated by the clamping assembly 42, as shown in FIG. 5. Alternatively, the at least one vibration sensor 1 can remain in contact with an oil tank 45 to detect the vibration generated by the oil tank 45, as shown in FIG. 6.

In the example where the at least one vibration sensor 1 is attached to the enclosure 44, two vibration sensors 1 can be used and respectively disposed on different sides (e.g., opposite sides) of the enclosure 44. In the example where the at least one vibration sensor 1 is attached to the clamping assembly 42, two vibration sensors 1 can be used and respectively disposed on different sides (e.g., opposite sides) of the clamping assembly 42. However, the above description is for exemplary purposes only, and is not meant to limit the scope of the present disclosure.

Referring to FIG. 1, the analysis device 2 can include a processing module 21. The processing module 21 is configured to perform preprocessing (such as classification and comparison) on the vibration data acquired by the at least one vibration sensor 1, and extract vibration feature parameters related to the vibration pattern of the transformer 4 (such as components of normal vibration frequencies) from the vibration data. Afterwards, the processing module 21 is configured to identify trends in the changes of the vibration feature parameters with respect to the tightening force, thereby establishing a correlation between the vibration condition of the transformer 4 and the tightening force, which is represented by a data-type construction model based on data correlations. Furthermore, the processing module 21 can analyze the vibration data to identify the vibration patterns of the transformer 4, for example, to identify the vibration mode of the transformer 4 by frequency-domain, time-domain, phase, or model-based analysis, which is advantageous for identifying the type and location of vibration abnormality. The processing module 21 can be a processing unit of a microcontroller or a general-purpose or special-purpose processor, but is not limited thereto.

The analysis device 2 can further include a storage module 22 and an output module 23. The storage module 22 is configured to store large volumes of vibration data and useful information generated from data processing and analysis. The storage module 22 can be a storage unit of the microcontroller or any form of memory, but is not limited thereto. The output module 23 is configured to transmit both the raw data and the useful information that can be processed and applied to the diagnostic device 3. The output module 23 can be a communication module or an output interface, but is not limited thereto.

In practice, as shown in FIG. 4, the analysis device 2 can further include a cabinet 24 that is disposed in proximity to the enclosure 44 of the transformer 4. The processing module 21, the storage module 22, and the output module 23 are integrated within the cabinet 24. For example, a printed circuit board B is installed inside the cabinet 24, and the processing module 21, the storage module 22, and the output module 23 are integrated on the printed circuit board B.

The diagnosis device 3 can include an alert module 31, an abnormality determination module 32, and a receiving module 33. The receiving module 33 is configured to receive any output from the output module 23. The abnormality determination module 32 is configured to accurately distinguish normal vibration from abnormal vibration during operation, according to the correlation between mechanical vibration and tightening force, and to transmit the vibration data related to the abnormal vibration to the alert module 31. The alert module 31 is configured to issue a warning message corresponding to the vibration data related to the abnormal vibration to all relevant personnel, so as to ensure that responsive actions can be promptly performed. For example, the warning message can be issued to terminal devices of management or maintenance staff.

In certain embodiments, the warning message can be in the form of a text message, email, or phone call. After receiving the warning message, the relevant personnel can immediately check the operation parameters and maintenance records of the transformer 4, and can perform preventive measures or conduct inspection or maintenance if necessary.

In the present embodiment, the abnormality determination module 32 is configured to determine, according to the correlation between mechanical vibration and tightening force, whether a type of abnormal vibration corresponds to a loose winding of the core assembly 41, a loose core of the core assembly 41, or deterioration of the insulation 43, and to locate the source of the abnormal vibration. Therefore, vibration issues can be more specifically understood and effectively addressed.

In practice, the diagnosis device 3 can be implemented on a network-enabled computer apparatus (e.g., operated on the network-enabled computer apparatus), in which each of the alert module 31, the abnormality determination module 32, and the receiving module 33 can be a software, hardware, or firmware. Furthermore, the diagnosis device 3 can access and utilize data on the analysis device 2 during the execution of a software application. Alternatively, the analysis device 2 can either actively transmit data to the diagnosis device 3, or transmit data to the diagnosis device 3 after receiving a query command.

### Second Embodiment

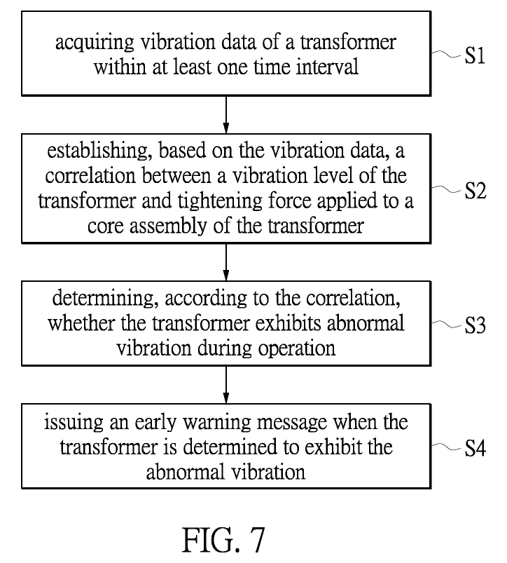

Referring to FIG. 7, a second embodiment of the present disclosure provides an abnormal vibration diagnosis method, which can be implemented by the abnormal vibration diagnosis system described in the first embodiment. The abnormal vibration diagnosis method of the present disclosure includes: step S1, acquiring vibration data of a transformer within at least one time interval; step S2, establishing, based on the vibration data, a correlation between a vibration level of the transformer and tightening force applied to a core assembly of the transformer; step S3, determining, according to the correlation, whether the transformer exhibits abnormal vibration during operation; and step S4, issuing an early warning message when the transformer is determined to exhibit the abnormal vibration.

Reference is made to FIGS. 1 and 4 to 6. In step S1, the vibration data of the transformer 4 can be acquired by at least one vibration sensor 1. The at least one vibration sensor 1 can be attached to a clamping assembly 42 or an enclosure 44 of the transformer 4. In step S2, the vibration patterns of the transformer 4 can be identified by analyzing the vibration data. In step S3, a type of abnormal vibration of the transformer 4 is determined to correspond to a loose winding of the core assembly 41, a loose core of the core assembly 41, or deterioration of the insulation 43, according to the correlation between mechanical vibration and tightening force as well as the vibration patterns, and to locate the source of the abnormal vibration.

The related technical features mentioned in the first embodiment are still valid in the present embodiment, and will not be repeated herein for the sake of brevity. Similarly, the related technical features mentioned in the present embodiment can be applied to the first embodiment.

### Beneficial Effects of the Embodiments

In conclusion, the abnormal vibration diagnosis system and method for a transformer provided by the present disclosure can promptly detect looseness in the core or clamping assembly and perform early warning accordingly, and if necessary, can initiate a maintenance measure to prevent transformer failure and ensure safe and stable operation of a power system, by virtue of acquiring vibration data of a transformer within at least one time interval, establishing a correlation between a vibration level of the transformer and a tightening force applied to a core assembly of the transformer, and determining whether the transformer exhibits abnormal vibration during operation according to the correlation.

Furthermore, the abnormal vibration diagnosis system and method for a transformer provided by the present disclosure can realize real-time monitoring, remote supervision, and condition prediction of transformer vibration conditions, fault diagnosis and prevention, thereby enhancing the reliability and safety of the transformer and reducing maintenance costs and labor requirements.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An abnormal vibration diagnosis method for a transformer, comprising:
acquiring vibration data of a transformer within at least one time interval, the transformer including a core assembly, a clamping assembly connected to the core assembly, and an insulator disposed between the core assembly and the clamping assembly, and the clamping assembly being configured to apply a tightening force to the core assembly;
establishing a correlation between transformer vibration level and tightening force based on the vibration data;
determining whether the transformer exhibits abnormal vibration during operation according to the correlation between transformer vibration level and tightening force; and
issuing an early warning message when the transformer is determined to exhibit the abnormal vibration.

2. The abnormal vibration diagnosis method according to claim 1, wherein the transformer includes an enclosure for accommodating the core assembly, the clamping assembly, and the insulator, and the vibration data is acquired by at least one vibration sensor that is attached to the enclosure.

3. The abnormal vibration diagnosis method according to claim 2, wherein the process of determining whether the transformer exhibits the abnormal vibration includes:
identifying a vibration pattern of the transformer by analyzing the vibration data; and
determining, according to the correlation between transformer vibration level and tightening force as well as the vibration pattern, whether the abnormal vibration corresponds to a loose winding of the core assembly, a loose core of the core assembly, or deterioration of the insulation;
wherein the warning message includes information indicating a type of the abnormal vibration.

4. The abnormal vibration diagnosis method according to claim 3, wherein the process of determining the type of the abnormal vibration includes identifying an occurrence location of the abnormal vibration by analyzing the vibration data.

5. The abnormal vibration diagnosis method according to claim 1, wherein the transformer includes an enclosure for accommodating the core assembly, the clamping assembly, and the insulator, and the vibration data is acquired by at least one vibration sensor that is attached to the clamping assembly.

6. The abnormal vibration diagnosis method according to claim 5, wherein the process of determining whether the transformer exhibits the abnormal vibration includes:
identifying a vibration pattern of the transformer by analyzing the vibration data; and
determining, according to the correlation between transformer vibration level and tightening force as well as the vibration pattern, whether the abnormal vibration corresponds to a loose winding of the core assembly, a loose core of the core assembly, or deterioration of the insulation;
wherein the warning message includes information indicating the type of the abnormal vibration.

7. The abnormal vibration diagnosis method according to claim 6, wherein the process of determining the type of the abnormal vibration includes identifying an occurrence location of the abnormal vibration by analyzing the vibration data.

8. An abnormal vibration diagnosis system for a transformer, comprising:
at least one vibration sensor configured to acquire vibration data of a transformer within at least one time interval, the transformer including a core assembly, a clamping assembly connected to the core assembly, and an insulator disposed between the core assembly and the clamping assembly, and the clamping assembly being configured to apply a tightening force to the core assembly;
an analysis device connected to the at least one vibration sensor, the analysis device being configured to establish, based on the vibration data, a correlation between transformer vibration level and tightening force; and
a diagnosis device connected to the analysis device, the diagnosis device being configured to determine, according to the correlation between transformer vibration level and tightening force, whether the transformer exhibits abnormal vibration during operation, and to issue an early warning message when the transformer is determined to exhibit the abnormal vibration.

9. The abnormal vibration diagnosis system according to claim 8, wherein the transformer includes an enclosure for accommodating the core assembly, the clamping assembly, and the insulator, and the vibration data is acquired by the at least one vibration sensor that is attached to the enclosure.

10. The abnormal vibration diagnosis system according to claim 9, wherein the analysis device is configured to identify a vibration pattern of the transformer by analyzing the vibration data, and the diagnosis device is configured to determine, according to the correlation between transformer vibration level and tightening force as well as the vibration pattern, whether the abnormal vibration corresponds to a loose winding of the core assembly, a loose core of the core assembly, or deterioration of the insulation; wherein the warning message includes information indicating the type of the abnormal vibration.

11. The abnormal vibration diagnosis system according to claim 10, wherein, in the process of determining the type of the abnormal vibration, the diagnosis device is configured to identify an occurrence location of the abnormal vibration by analyzing the vibration data.

12. The abnormal vibration diagnosis system according to claim 8, wherein the transformer includes an enclosure for accommodating the core assembly, the clamping assembly, and the insulator, and the at least one vibration sensor is attached to the clamping assembly.

13. The abnormal vibration diagnosis system according to claim 12, wherein the analysis device is configured to identify a vibration pattern of the transformer by analyzing the vibration data, and the diagnosis device is configured to determine, according to the correlation between transformer vibration level and tightening force as well as the vibration pattern, whether the abnormal vibration corresponds to a loose winding of the core assembly, a loose core of the core assembly, or deterioration of the insulation; wherein the warning message includes information indicating the type of the abnormal vibration.

14. The abnormal vibration diagnosis system according to claim 13, wherein, in the process of determining the type of the abnormal vibration, the diagnosis device is configured to identify an occurrence location of the abnormal vibration by analyzing the vibration data.
